(19) United States
(12) Patent Application Publication
(10) Pub. No.: US 2024/0395656 A1
(43) Pub. Date: Nov. 28, 2024

(54) Components For Increased Power Handling

(71) Applicant: KYOCERA AVX Components Corporation, Fountain Inn, SC (US)

(72) Inventors: Cory Nelson, Simpsonville, SC (US); Shelby Bartley, Simpsonville, SC (US); Thomas Delvaux, Fountain Inn, SC (US)

(21) Appl. No.: 18/650,179

(22) Filed: Apr. 30, 2024

Related U.S. Application Data
(60) Provisional application No. 63/503,500, filed on May 22, 2023.

(51) Int. Cl. H01L 23/367; H01L 21/3213; H01L 21/768; H01L 23/373

(52) U.S. Cl. CPC H01L 23/3675; H01L 21/3213; H01L 21/76879; H01L 23/3731

(57) ABSTRACT

A component assembly can include an electrical component disposed on a heat sink component to mechanically stabilize the electrical component such that the electrical component may be relatively thin. For example, the heat sink component can include a heat sink substrate comprising a thermally conductive material that is electrically non-conductive. The heat sink substrate can have a first surface and a second surface opposite the first surface, with an electrically conductive layer formed over the second surface of the heat sink substrate. The electrical component can include a component substrate having a first surface and a second surface opposite the first surface, and an electrically conductive pattern can be formed over the first surface of the component substrate. The second surface of the component substrate can be disposed adjacent the first surface of the heat sink substrate.

### RELATED APPLICATION

The present application is based upon and claims priority to U.S. Provisional Patent Application Ser. No. 63/503,500, having a filing date of May 22, 2023, which is incorporated herein by reference.

### BACKGROUND

Electrical circuits, such as power amplifier circuits, generate heat during normal operation. Heat build-up may undesirably increase the temperature of the various components of the electrical circuit. If this heat is not sufficiently managed, for example by dissipation to a heat sink, the electrical device may overheat, resulting in damage to the electrical component. Further, some components may utilize a thicker substrate to ensure structural integrity, which can hinder heat dissipation and, in turn, limit the power handling capability of the component. Improved heat dissipation would be welcomed in the art.

### SUMMARY

In accordance with one embodiment of the present invention, a component assembly includes a heat sink component including a heat sink substrate comprising a thermally conductive material that is electrically non-conductive. The heat sink substrate has a first surface and a second surface opposite the first surface. The heat sink component further includes a second electrically conductive layer formed over the second surface of the heat sink substrate. The component assembly also includes an electrical component including a component substrate having a first surface and a second surface opposite the first surface, and an electrically conductive pattern formed over the first surface of the component substrate. The electrical component is disposed on the heat sink component such that the second surface of the component substrate is adjacent the first surface of the heat sink substrate.

In accordance with another embodiment of the present invention, a method of forming a component assembly includes depositing a conductive material over a second surface of a heat sink substrate to form a second electrically conductive layer on the heat sink substrate. The heat sink substrate includes a thermally conductive material that is electrically non-conductive, and the second surface of the heat sink substrate is opposite a first surface of the heat sink substrate. The method also includes forming an electrically conductive pattern over a first surface of a component substrate of an electrical component. The component substrate has a second surface opposite the first surface. The component substrate is disposed on the heat sink substrate such that the second surface of the component substrate is adjacent the first surface of the heat sink substrate.

### BRIEF DESCRIPTION OF THE DRAWINGS

A full and enabling disclosure of the present invention, including the best mode thereof, directed to one of ordinary skill in the art, is set forth more particularly in the remainder of the specification, which makes reference to the appended figures in which:

FIG. 1 is a perspective view of a component assembly according to aspects of the present disclosure;

FIG. 2 is a perspective view of a heat sink component of the component assembly of FIG. 1 according to aspects of the present disclosure;

FIG. 3 is a perspective view of another embodiment of the heat sink component of FIG. 2 according to aspects of the present disclosure;

FIG. 4 is a perspective view of an electrical component of the component assembly of FIG. 1 according to aspects of the present disclosure;

FIG. 5 is a perspective view of the component assembly of FIG. 1 prior to reducing a thickness of a component substrate of the electrical component and prior to depositing an electrically conductive pattern on an exposed surface of the electrical component according to aspects of the present disclosure;

FIG. 6 is a perspective view of the component assembly of FIG. 1 assembled with a device according to aspects of the present disclosure; and

FIG. 7 is a flow chart illustrating a method of forming a component assembly according to aspects of the present disclosure.

Repeat use of reference characters in the present specification and drawing is intended to represent same or analogous features or elements of the invention.

### DETAILED DESCRIPTION

It is to be understood by one of ordinary skill in the art that the present discussion is a description of exemplary embodiments only and is not intended as limiting the broader aspects of the present invention, which broader aspects are embodied in the exemplary construction.

Generally speaking, the present invention is directed to relatively thin components having features for managing heat flow away from the components and for providing mechanical integrity to the components. For example, a component assembly may include an electrical component disposed on a heat sink component, which can help direct heat away from the electrical component as well as provide stability to the relatively thin electrical component. One or more electrically conductive layers may extend over one or more surfaces of the heat sink component or the electrical component, which may provide additional mechanical integrity to the assembly and may also facilitate electrical and thermal connectivity between the electrical component and the heat sink component. The electrical component may have a thickness such that, for example, a ratio of the overall thickness of the assembly to the electrical component thickness is, e.g., at least about 2.

Processing a substrate of the electrical component to reduce its thickness, e.g., after joining the substrate of the electrical component to a heat sink component as described herein, can allow the electrical component to be thinned more than previously allowed, e.g., to relatively extreme levels. The heat sink component, which can include metal layers or the like, increases the mechanical strength of the assembly to allow the thickness of the electrical component can be reduced to such relatively extreme levels without comprising the functionality or viability of the part. Further, the thinner electrical component substrate can facilitate faster transmission of heat through the part to manage heat flow more effectively through the electrical component. The substrate of the heat sink component can be selected to further facilitate, rather than frustrate, heat flow away from the electrical component. Because greater or higher power through the part increases the part temperature or heat in the part, more effective heat flow management can increase power handling of the part. That is, faster transmission of heat away from the part can allow the part to handle higher power.

In some embodiments, a component assembly includes a heat sink component having a heat sink substrate including a thermally conductive material that is electrically non-conductive. An electrically conductive layer can be formed over one surface of the heat sink substrate. In some embodiments, another electrically conductive layer is formed over an opposite surface of the heat sink substrate. As such, the heat sink component can include a first electrically conductive layer formed over a first surface of the heat sink substrate and a second electrically conductive layer formed over a second surface of the heat sink substrate, where the second surface is opposite the first surface. It will be appreciated that, in some embodiments, the heat sink component may include only one electrically conductive layer, while in other embodiments, the heat sink component includes at least two electrically conductive layers.

In some embodiments, the electrical component includes a component substrate having a first surface and a second surface opposite the first surface. The electrical component can be disposed on the heat sink component such that the second surface of the component substrate is adjacent the first surface of the heat sink substrate.

In some embodiments, the electrical component includes an electrically conductive layer formed over the second surface of the component substrate. In such embodiments, the electrically conductive layer of the electrical component can contact the first surface of the heat sink component or the first electrically conductive layer of the heat sink component, in embodiments in which the first electrically conductive layer is formed over the first surface of the heat sink substrate.

In some embodiments, the first electrically conductive layer of the heat sink component is joined to the electrically conductive layer of the electrical component. That is, when the electrical component is disposed on the heat sink component, the two components can be joined together. In embodiments including the first electrically conductive layer of the heat sink component and the electrically conductive layer of the electrical component, the first electrically conductive layer can be joined to the electrically conductive layer of the electrical component with an adhesive, such as a polymer adhesive like an epoxy resin or any suitable adhesive. In other embodiments, the first electrically conductive layer is a first metal layer and the electrically conductive layer of the electrical component is a component metal layer, and the first metal layer can be joined to the component metal layer through a metalized connection.

In some embodiments, at least one electrically conductive layer extends over the entirety of the respective surface the layer is formed over. For example, the first electrically conductive layer extends over the entirety of the first surface of the heat sink substrate, the second electrically conductive layer extends over the entirety of the second surface of the heat sink substrate, and/or the electrically conductive layer of the electrical component extends over the entirety of the second surface of the component substrate. As such, one or more of the electrically conductive layers may extend over only a portion of, rather than the entirety of, the respective surface the layer is formed over. For instance, a respective electrically conductive layer may be spaced apart from one or more edges defining the surface over which the layer is formed.

In some embodiments, a gap is formed in at least one of the first electrically conductive layer or the electrically conductive layer of the electrical component for receipt of an adhesive. More particularly, for embodiments of the heat sink component including the first electrically conductive layer, a gap, opening, depression, or the like may be formed or defined in the conductive material of the layer. Such gap, opening, depression, etc. defines a space for receipt of adhesive such that when the electrical component is positioned against the first electrically conductive layer, at least a portion of the adhesive remains in place to bond together the heat sink component and the electrical component. In other embodiments, e.g., embodiments in which the first electrically conductive layer of the heat sink component is omitted, such gap, etc. may be formed in the electrically conductive layer formed over the second surface of the component substrate, which contacts the heat sink component when the electrical component is disposed on the heat sink component. It will be appreciated that, without such space for the adhesive, the adhesive would extend only over the contact surfaces of the heat sink component and the electrical component and could be forced to travel outward to the boundary of the components when the components are brought together.

In some embodiments, one or more vias are formed in the heat sink substrate. For example, at least one via can extend through the heat sink substrate from the first electrically conductive layer to the second electrically conductive layer. In some embodiments, the at least one via includes a conductive material to electrically connect the first electrically conductive layer and the second electrically conductive layer. For instance, the at least one via may be plated or otherwise lined with the conductive material.

As described herein, the original first surface of the conductive substrate, which is free of electrically conductive material, can be processed to reduce the thickness of the component substrate. As one example, the component substrate can be ground along its original first surface to reduce the thickness of the component substrate. Other techniques for removing substrate material may be used as well.

After processing to reduce the component substrate thickness, the component substrate may have a thickness less than about 600 μm (micrometers or microns). In some embodiments, the component substrate may have a thickness less than about 500 μm, in some embodiments less than about 250 μm, in some embodiments less than about 125 μm, and in some embodiments less than about 75 μm. The thickness of the component substrate may be within a range of about 50 μm to about 600 μm, such as within a range of about 75 μm to about 500 μm, within a range of about 100 μm to about 400 μm, or within a range of about 150 μm to about 300 μm.

In some embodiments, the heat sink substrate may have a thickness of at least about 100 μm to about 1500 μm. For example, the thickness of the heat sink substrate may be about 100 μm or more, about 125 μm or more, about 250 μm or more, about 500 μm or more, about 1000 μm or more, or about 1250 μm or more. In some embodiments, the thickness of the heat sink substrate may be within a range of about 100 μm to about 1500 μm, such as within a range of about 150 μm to about 1250 μm, within a range of about 250 μm to about 1000 μm, or within a range of about 300 μm to about 750 μm.

In some embodiments, a ratio of the thickness of the heat sink substrate to the thickness of the component substrate may be at least about 0.2. In some embodiments, the ratio of the thickness of the heat sink substrate to the thickness of the component substrate may be at least about 0.5, in some embodiments at least about 1, in some embodiments at least about 5, in some embodiments at least about 10, and in some embodiments at least about 20. For instance, the ratio of the thickness of the heat sink substrate to the thickness of the component substrate 120 may be within a range of about 0.2 to about 25, such as within a range of about 0.25 to about 20 or within a range of about 1 to about 15.

Further, in some embodiments, a ratio of an overall thickness of the component to a thickness of the component substrate is at least about 1.1. In some embodiments, the ratio of the overall thickness of the component to the thickness of the component substrate may be at least about 2, in some embodiments at least about 3, in some embodiments at least about 5, in some embodiments at least about 10, and in some embodiments at least about 25. For instance, the ratio of the overall thickness of the component to the thickness of the component substrate may be within a range of about 2 to about 30, such as within a range of about 3 to about 25 or within a range of about 5 to about 20.

After processing the component substrate, the component substrate includes the first surface (rather than the original first surface) opposite the second surface, over which is formed the electrically conductive layer. In some embodiments, an electrically conductive pattern can be formed over the first surface of the component substrate. The electrically conductive pattern can include conductive material arranged in any pattern, such as to define the functionality or features of the electrical component. As one example, the electrically conductive pattern can include a resistive element connected between a first terminal and a second terminal. As further examples, the electrically conductive pattern may include one or more passive components, such as one or more capacitors, inductors, resistors, or transmission lines in series or parallel to form individual components, and/or the electrically conductive pattern may include various circuits such as filters, splitters, attenuators, diplexers, etc.

The electrically conductive pattern formed on the component substrate can include one or more thin film components. The one or more thin film components can include one or more of a resistor, varistor, capacitor, inductor, and/or combinations thereof, such as a thin film filter. The thin film components may include one or more layers of conductive materials, dielectric materials, resistive materials, inductive materials, or other materials that are precisely formed using “thin film” technology.

As one example, the electrically conductive pattern can include a thin film varistor. The varistor can include barium titanate, zinc oxide, or any other suitable dielectric material. Various additives may be included in the dielectric material, for example, that produce or enhance the voltage-dependent resistance of the dielectric material. For example, in some embodiments, the additives may include oxides of cobalt, bismuth, manganese, or a combination thereof. In some embodiments, the additives may include oxides of gallium, aluminum, antimony, chromium, titanium, lead, barium, nickel, vanadium, tin, or combinations thereof. The dielectric material may be doped with the additive(s) ranging from about 0.5 mole percent to about 3 mole percent, and in some embodiments from about 1 mole percent to about 2 mole percent. The average grain size of the dielectric material may contribute to the non-linear properties of the dielectric material. In some embodiments, the average grain size may range from about 1 micron to 100 microns, in some embodiments, from about 2 microns to 80 microns.

As another example, the thin film component(s) can include a thin film resistor including one or more resistive layers. For example, the resistive layer may include tantalum nitride (TaN), nickel chromium (NiCr), tantalum aluminide, chromium silicon, titanium nitride, titanium tungsten, tantalum tungsten, oxides and/or nitrides of such materials, and/or any other suitable thin film resistive materials. The resistive layer may have any suitable thickness.

As another example, the thin film component(s) can include a thin film capacitor including one or more dielectric layers. As examples, the dielectric layer(s) may include one or more suitable ceramic materials. Example suitable materials include alumina (Al₂O₃), aluminum nitride (AlN), beryllium oxide (BeO), aluminum oxide (Al₂O₃), boron nitride (BN), silicon (Si), silicon carbide (SiC), silica (SiO2), silicon nitride (Si3N4), gallium arsenide (GaAs), gallium nitride (GaN), zirconium dioxide (ZrO2), mixtures thereof, oxides and/or nitrides of such materials, or any other suitable ceramic material. Additional example ceramic materials include barium titanate (BaTiO3), calcium titanate (CaTiO3), zinc oxide (ZnO), ceramics containing low-fire glass, or other glass-bonded materials. Dielectric materials such as diamond and cubic boron arsenide may be used as well.

The thin film component can include one or more layers having thicknesses ranging from about 0.001 μm to about 1,000 μm, in some embodiments from about 0.01 μm to about 100 μm, in some embodiments from about 0.1 μm to about 50 μm, in some embodiments from about 0.5 μm to about 20 μm. The respective layer(s) of materials forming thin film component may be applied using specialized techniques based on etching, photolithography, PECVD (Plasma Enhanced Chemical Vapor Deposition) processing or other techniques.

The heat sink substrate of the heat sink component may include any suitable material having a generally low thermal resistivity (e.g., less than about 6.67×10−3 m·° C./W), and a generally high electrical resistivity (e.g., greater than about 1014 Ω·cm). A thermal resistivity of 6.67×10−3 m·° C./W is equivalent with a thermal conductivity of about 150 W/m·° C. In other words, suitable materials for the heat sink substrate may have a generally high thermal conductivity, such as greater than about 150 W/m·° C.

For example, in some embodiments, the heat sink substrate may be made from a material having a thermal conductivity between about 100 W/m·° C. and about 300 W/m·° C. at about 22° C. In other embodiments, the heat sink substrate may be made from a material having a thermal conductivity between about 125 W/m·° C. and about 250 W/m·° C. at about 22° C. In other embodiments, the heat sink substrate may be made from a material having a thermal conductivity between about 150 W/m·° C. and about 200 W/m·° C. at about 22° C.

In some embodiments, the heat sink substrate may comprise aluminum nitride, beryllium oxide, aluminum oxide, boron nitride, silicon nitride, magnesium oxide, zinc oxide, silicon carbide, any suitable ceramic material, and mixtures thereof.

In some embodiments, the heat sink substrate may include aluminum nitride. For example, in some embodiments the heat sink substrate may be made from any suitable composition including aluminum nitride. In some embodiments, the heat sink substrate may be made primarily from aluminum nitride, e.g., the heat sink substrate may also contain additives or impurities. In other embodiments, the heat sink substrate may include beryllium oxide. For example, in some embodiments the heat sink substrate may be made from any suitable composition including beryllium oxide. In some embodiments, the heat sink substrate may be made primarily from beryllium oxide, e.g., the heat sink substrate may also contain additives or impurities.

The component substrate of the electrical component may include one or more dielectric materials. In some embodiments, the one or more dielectric materials may have a low dielectric constant. The dielectric constant may be less than about 100, in some embodiments less than about 75, in some embodiments less than about 50, in some embodiments less than about 25, in some embodiments less than about 15, and in some embodiments less than about 5. For example, in some embodiments, the dielectric constant may range from about 1.5 and 100, in some embodiments from about 1.5 to about 75, and in some embodiments from about 2 to about 8. The dielectric constant may be determined in accordance with IPC TM-650 2.5.5.3 at an operating temperature of 25° C. and frequency of 1 MHz. The dielectric loss tangent may range from about 0.001 to about 0.04, in some embodiments from about 0.0015 to about 0.0025.

In some embodiments, the one or more dielectric materials may include organic dielectric materials. Example organic dielectric include polyphenyl ether (PPE) based materials, such as LD621 from Polyclad and N6000 series from Park/Nelco Corporation, liquid crystalline polymer (LCP), such as LCP from Rogers Corporation or W. L. Gore & Associates, Inc., hydrocarbon composites, such as 4000 series from Rogers Corporation, and epoxy-based laminates, such as N4000 series from Park/Nelco Corp. For instance, examples include epoxy based N4000-13, bromine-free material laminated to LCP, organic layers with high K material, unfilled high-K organic layers, Rogers 4350, Rogers 4003 material, and other theremoplastic materials such as polyphenylene sulfide resins, polyethylene terephthalate resins, polybutylene terephthalate resins, polyethylene sulfide resins, polyether ketone resins, polytetraflouroethylene resins and graft resins, or similar low dielectric constant, low-loss organic material.

In some embodiments, the one or more dielectric materials may include a ceramic-filled epoxy. For example, the one or more dielectric materials may include an organic compound, such as a polymer (e.g., an epoxy) and may contain particles of a ceramic dielectric material, such as barium titanate, calcium titanate, zinc oxide, alumina with low-fire glass, or other suitable ceramic or glass-bonded materials.

Other materials may be utilized, however, including, N6000, epoxy based N4000-13, bromine-free material laminated to LCP, organic layers with high K material, unfilled high-K organic layers, Rogers 4350, Rogers 4003 material (from the Rogers Corporation), and other theremoplastic materials such as hydrocarbon, Teflon, FR4, epoxy, polyamide, polyimide, and acrylate, polyphenylene sulfide resins, polyethylene terephthalate resins, polybutylene terephthalate resins, polyethylene sulfide resins, polyether ketone resins, polytetraflouroethylene resins, BT resin composites (e.g., Speedboard C), thermosets (e.g., Hitachi MCL-LX-67F), and graft resins, or similar low dielectric constant, low-loss organic material.

Additionally, non-organic dielectric materials may be used including a ceramic, semi-conductive, or insulating materials, such as, but not limited to barium titanate, calcium titanate, zinc oxide, alumina with low-fire glass, or other suitable ceramic or glass-bonded materials. Alternatively, the dielectric material may be an organic compound such as an epoxy (with or without ceramic mixed in, with or without fiberglass), popular as circuit board materials, or other plastics common as dielectrics. In these cases, the conductor may be a copper foil which is chemically etched to provide the patterns. In still further embodiments, dielectric material may comprise a material having a relatively high dielectric constant (K), such as one of NPO (COG), X7R, X5R X7S, Z5U, Y5V and strontium titanate. In such examples, the dielectric material may have a dielectric constant that is greater than 100, for example within a range from between about 100 to about 4000, in some embodiments from about 1000 to about 3000.

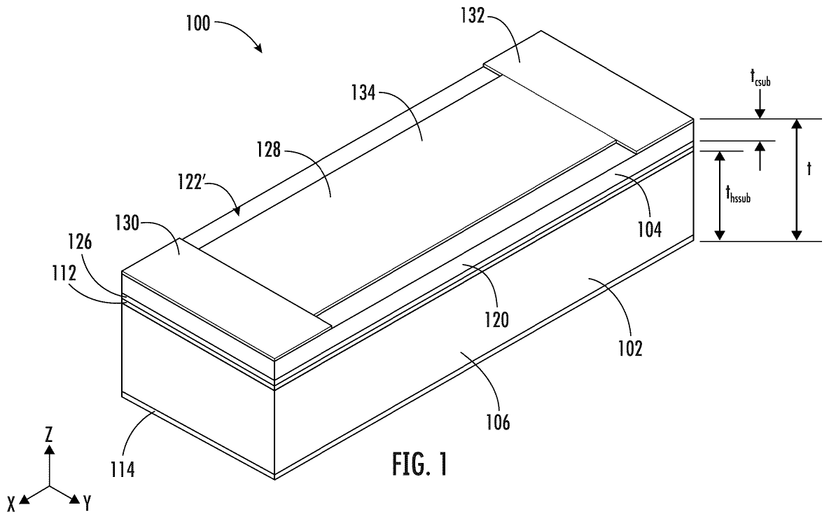

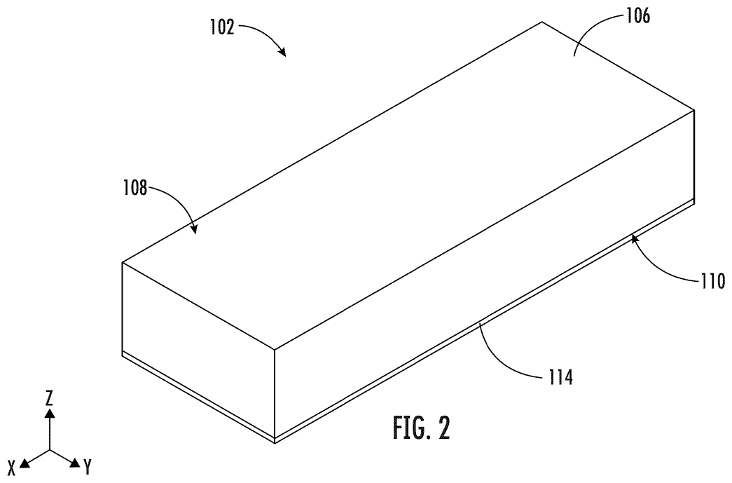

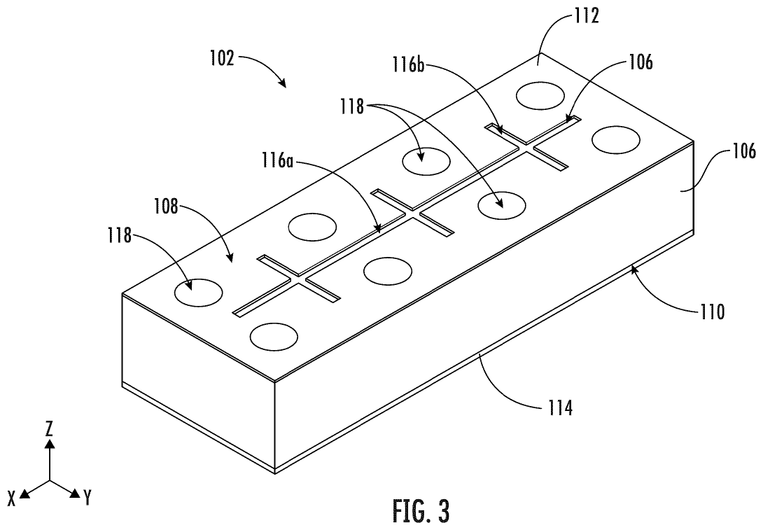

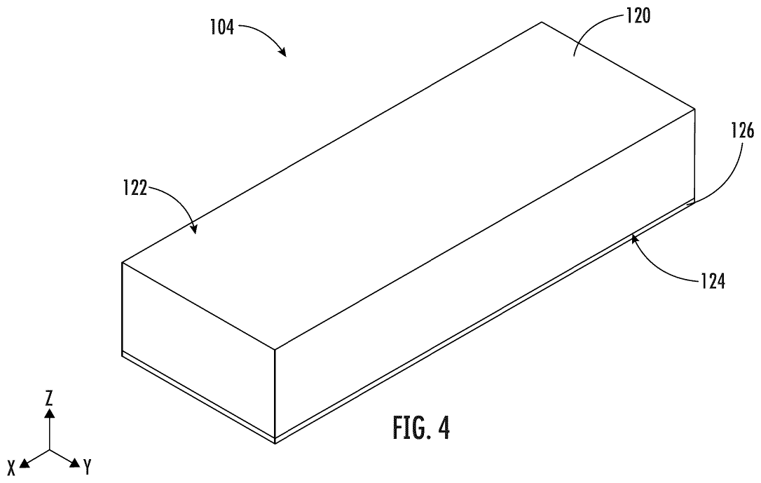

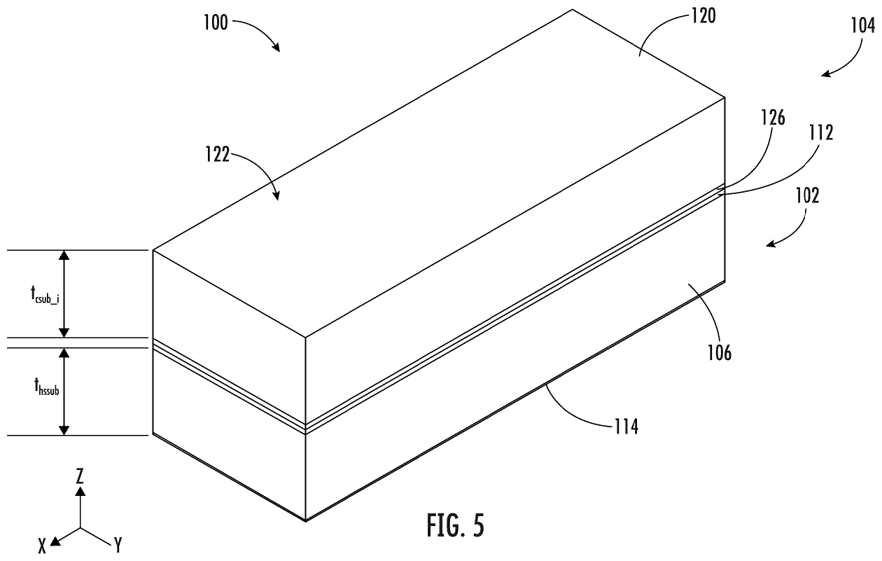

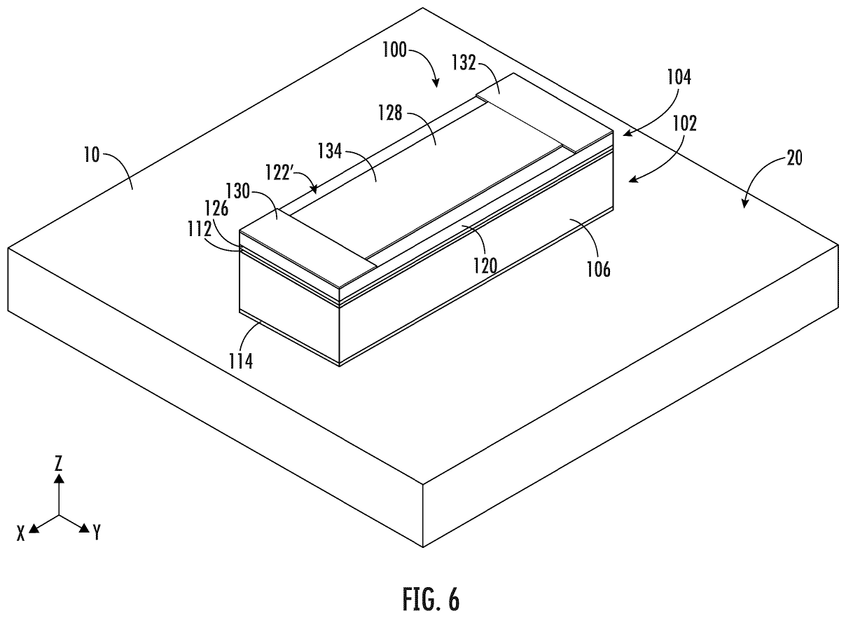

Referring now to the figures, FIG. 1 illustrates a component assembly 100 including a heat sink component 102 and an electrical component 104. FIGS. 2 and 3 illustrate embodiments of the heat sink component 102, and FIG. 4 depicts an embodiment of the electrical component 104. FIG. 5 provides a view of the component assembly 100 prior to thinning and patterning the electrical component 104. FIG. 6 illustrates the component assembly 100 mounted on a mounting surface 20 of a device 10, such as a printed circuit board (PCB) or the like.

As shown in FIG. 1, the electrical component 104 is disposed on the heat sink component 102. Referring to FIG. 2, the heat sink component 102 includes a heat sink substrate 106 having a first surface 108 and a second surface 110, which is opposite the first surface 108. The heat sink substrate 106 includes a thermally conductive material that is electrically non-conductive. For example, the heat sink substrate may include any suitable material having a generally low thermal resistivity and a generally high electrical resistivity, such as aluminum nitride, beryllium oxide, or any other such material as described elsewhere herein.

As illustrated in FIG. 2, an electrically conductive layer 114 may be formed over the second surface 110 of the heat sink substrate 106. The electrically conductive layer 114 may be formed from a material including a metal, such that the electrically conductive layer 114 may also be referred to as a metal layer. For example, the electrically conductive or metal layer 114 may be formed from a metallic material such as copper, nickel, gold, silver, or other metals or alloys. Other exemplary materials for forming the conductive layer 114 are described elsewhere herein. Further, the electrically conductive layer 114 may extend over the entirety of or just a portion of the second surface 110 of the heat sink substrate 106.

Referring now to FIG. 3, in some embodiments, an electrically conductive layer 112 may be formed over the first surface 108 of the heat sink substrate 106. For embodiments including both electrically conductive layers 112, 114, the electrically conductive layer 112 may be referred to as the first electrically conductive layer 112, and the electrically conductive layer 114 may be referred to as the second electrically conductive layer 114. The first electrically conductive layer 112 may be formed from a material including a metal, such that the first electrically conductive layer 112 may also be referred to as a metal layer. In embodiments where both the first electrically conductive layer 112 and the second electrically conductive layer 114 are metal layers, the first electrically conductive layer 112 may be referred to as the first metal layer and the second electrically conductive layer 114 may be referred to as the second metal layer. The first electrically conductive or first metal layer 112 and/or the second electrically conductive or second metal layer 114 may be formed from a metallic material such as copper, nickel, gold, silver, or other metals or alloys. Other exemplary materials for forming the first electrically conductive layer 112 are described elsewhere herein.

The first electrically conductive layer 112 may extend over the entirety of or just a portion of the first surface 108 of the heat sink substrate 106. For example, as shown in FIG. 3, the first electrically conductive layer 112 extends to each of the four edges defining the extent of the first surface 108 of the heat sink substrate 106, but a gap 116 is formed or defined in the first electrically conductive layer 112 such that no electrically conductive material is within the gap 116. As depicted in FIG. 3, the gap 116 may have a body 116a that extends lengthwise along a longitudinal direction X defined by the heat sink substrate 106 and have one or more arms 116b that extend widthwise along a lateral direction Y defined by the heat sink substrate 106.

The gap 116 may receive an adhesive to join together the heat sink component 102 and the electrical component 104 as shown in FIG. 1. That is, the gap 116 may provide a receptacle or the like for the adhesive such that at least a portion of the adhesive does not squeeze or run out of the component assembly 100 when the heat sink component 102 and the electrical component 104 are brought together. The adhesive may be a polymer adhesive, such as an epoxy or the like, or any other suitable type of adhesive. In other embodiments, the heat sink component 102 and the electrical component 104 may be joined together using other types of connections, as described elsewhere herein.

The first electrically conductive layer 112 and/or the second electrically conductive layer 114 of the heat sink component 102 may impart additional structural integrity to the heat sink component 102 and the component assembly 100. That is, the first electrically conductive layer 112 and/or the second electrically conductive layer 114 can add mechanical strength to the heat sink component 102 and, when assembled with the electrical component 104 to form the component assembly 100, can enhance the mechanical strength of the component assembly 100. The material from which the first electrically conductive layer 112 and/or the second electrically conductive layer 114 is formed can be selected to provide the desired mechanical strength to the component assembly 100. The mechanical strength or stability provided by the electrically conductive layer(s) 112, 114 may allow the component substrate 120 (FIGS. 4, 5) of the electrical component 104 to be thinned to a relatively thin thickness as described elsewhere herein. Moreover, the first electrically conductive layer 112 and/or the second electrically conductive layer 114 can provide an electrical connection between and/or through the heat sink component 102 and the electrical component 104 as described herein.

As further illustrated in FIG. 3, at least one via 118 extends through the heat sink substrate 106 from the first electrically conductive layer 112 to the second electrically conductive layer 114. In the depicted embodiment, eight total vias 118 are defined in the heat sink substrate 106 and are arranged in two rows of four vias 118 spaced apart from one another along the longitudinal direction X, with the rows spaced apart from one another along the lateral direction Y. In some embodiments, the at least one via 118 may include a conductive material to electrically connect the first electrically conductive layer 112 and the second electrically conductive layer 114. It will be appreciated that the multiple vias 118 shown in FIG. 3 are by way of example only, and any suitable number and arrangement of vias 118 may be used, e.g., to electrically connect the first electrically conductive layer 112 and the second electrically conductive layer 114.

Turning now to FIG. 4, the electrical component 104 can include a component substrate 120. The component substrate has an original first surface 122 and a second surface 124 opposite the original first surface 122. Similar to the heat sink component 102, the electrical component can include an electrically conductive layer 126 formed over the second surface 124 of the component substrate 120. Like the first and second electrically conductive layers 112, 114 of the heat sink component 102, the electrically conductive layer 126 of the electrical component 104 can be formed from any suitable electrically conductive material, such as a metal or a material containing a metal. The electrically conductive layer 126 may be called a metal layer when formed from a material containing at least one metal. Further, the electrically conductive layer 126 extends over at least a portion of the second surface 124 of the component substrate 120. In some embodiments, the electrically conductive layer 126 extends over the entirety of the second surface 124 of the component substrate 120.

Also similar to the first and second electrically conductive layers 112, 114 of the heat sink component 102, the electrically conductive layer 126 of the electrical component 104 may provide mechanical strength to the component substrate 120 while also providing an electrical connection between the heat sink component 102 and the electrical component 104. As one example, the electrically conductive layer 126 may be formed from a material having a higher stiffness than the component substrate 120, thereby increasing the mechanical strength of the electrical component 104. As described herein, the mechanical integrity imparted by the electrically conductive layer 126, as well as the heat sink component 102, may allow the component substrate 120 to be thinned to a thickness less than a typical thickness, as particular examples, less than a typical thickness for components of a larger size or footprint.

Referring to FIG. 5, the electrical component 104 can be assembled with the heat sink component 102 to form the component assembly 100. For example, the second surface 124 of the component substrate 120 may be adjacent the first surface 108 of the heat sink substrate 106. An adhesive (not shown) may be applied between the heat sink component 102 and the electrical component 104 to join together the two components 102, 104. For instance, as described above, a gap 116 may be formed in at least one of the first electrically conductive layer 112 disposed over the first surface 108 of the heat sink substrate 106 or the electrically conductive layer 126 formed over the second surface 124 of the component substrate 120. Although not depicted in the figures, it will be appreciated that a gap 116 defined in the electrically conductive layer 126 of the electrical component 104 may be configured similarly to the gap 116 illustrated with respect to the heat sink component 102. At least a portion of the adhesive may be received in the gap(s) 116, e.g., such that at least a portion of the adhesive remains between the heat sink component 102 and the electrical component 104 when they are brought into contact with one another. More particularly, although bringing the components 102, 104 into contact with one another may cause the adhesive to spread and possibly travel beyond the edges of the components 102, 104, the gap 116 helps ensure at least some adhesive remains between the components 102, 104 to join them together. It will be appreciated that the adhesive may be any suitable substance or material for holding together the heat sink component 102 and the electrical component 104, such as an epoxy (or epoxy resin) or other bonding agent.

The heat sink component 102 and the electrical component 104 may be joined together or bonded to one another in other ways as well. As one example, a metalized connection may be formed between the components 102, 104. More particularly, in embodiments including the first electrically conductive layer 112 formed over the first surface 108 of the heat sink substrate 106 and the electrically conductive layer 126 formed over the second surface 124 of the component substrate 120, the first electrically conductive layer 112 can contact the electrically conductive layer 126 when the electrical component 104 is stacked with the heat sink component 102 as shown in FIG. 5. In embodiments in which the first electrically conductive layer 112 is a first metal layer and the electrically conductive layer 126 is a component metal layer, the first metal layer can be joined to the component metal layer through a metalized connection. For instance, the metal layers may be soldered together, heat may be selectively applied to melt the metal layers together in at least one location, etc.

After joining the electrical component 104 to the heat sink component 102, the electrical component 104 may be reduced in thickness. For example, the original first surface 122 of the component substrate 120 can remain exposed after joining together the components 102, 104. The component substrate 120 may be processed, e.g., ground or the like, along the original first surface 122 to reduce the thickness of the component substrate 120 and, thereby, the electrical component 104. After processing, the component substrate 120 has a first surface 122′ opposite the second surface 124, with a thickness t_{csub} defined between the first surface 122′ and the second surface 124.

The thickness of the electrical component 104 may be reduced after joining the electrical component 104 to the heat sink component 102, rather than before joining the components 102, 104, because the heat sink component 102 may provide additional mechanical stability to the electrical component 104. Further, the mechanical stability provided by the heat sink component 102 may allow the component substrate 120 to be thinned to a thickness less than previously achieved.

For example, the component substrate 120 may have a thickness t_{csub} less than about 75 μm (micrometers or microns). In some embodiments, the component substrate 120 may have a thickness t_{csub} less than about 125 μm, in some embodiments less than about 250 μm, and in some embodiments less than about 500 μm. The thickness t_{csub} of the component substrate 120 may be within a range of about 50 μm to about 600 μm, such as within a range of about 75 μm to about 500 μm, within a range of about 100 μm to about 400 μm, or within a range of about 150 μm to about 300 μm.

Moreover, a ratio of a thickness t_{hssub} of the heat sink substrate 106 to the thickness t_{csub} of the component substrate 120 may be at least about 0.2. In some embodiments, the ratio of the thickness t_{hssub} of the heat sink substrate 106 to the thickness t_{csub} of the component substrate 120 may be at least about 0.5, in some embodiments at least about 1, in some embodiments at least about 5, in some embodiments at least about 10, and in some embodiments at least about 20. For instance, the ratio of the thickness t_{hssub} of the heat sink substrate 106 to the thickness t_{csub} of the component substrate 120 may be within a range of about 0.2 to about 25, such as within a range of about 0.25 to about 20 or within a range of about 1 to about 15.

Further, a ratio of an overall thickness t of the component assembly 100 to a thickness of the component substrate t_{csub} is at least about 1.1. In some embodiments, the ratio of the overall thickness t of the component assembly 100 to the thickness t_{csub} of the component substrate 120 may be at least about 2, in some embodiments at least about 3, in some embodiments at least about 5, in some embodiments at least about 10, and in some embodiments at least about 25. For instance, the ratio of the overall thickness t of the component assembly 100 to the thickness t_{csub} of the component substrate 120 may be within a range of about 2 to about 30, such as within a range of about 3 to about 25 or within a range of about 5 to about 20.

It will be appreciated that the component substrate 120 also may thinned (or reduced in thickness) in multiple iterations. For instance, the component substrate 120 may be subjected to a first processing after forming the electrically conductive layer 126 over the second surface 124 of the component substrate 120, with the component substrate 120 being processed (e.g., ground, etc.) along the original first surface 122. After joining the electrical component 104 to the heat sink component 102, the component substrate 120 may be subjected to a second processing, with the component substrate 120 being processed along the surface exposed through the first processing process. Other methods of reducing the thickness of the component substrate 120 of the electrical component 104 may be used as well.

Referring back to FIG. 1, an electrically conductive pattern 128 may be formed over the first surface 122′ of the component substrate 120 of the electrical component 104. That is, after thinning the component substrate 120, an electrical pathway may be formed over the exposed surface 122′ of the component substrate 120. In some embodiments, the electrically conductive pattern 128 includes one or more thin film components. As one example, as illustrated in FIG. 1, the electrically conductive pattern 128 can include a first terminal 130, a second terminal 132, and a resistive element 134 extending from the first terminal 130 to the second terminal 132. The resistive element 134 may be, e.g., a thin film resistor formed from one or more resistive layers or a thin film varistor. It will be appreciated, however, that the electrically conductive pattern 128 illustrated herein is by way of example only, and the electrically conductive pattern 128 may incorporate any desired electrical elements or conductive pathway shapes, designs, or constructions. For instance, the electrically conductive pattern 128 may include one or more passive components, such as one or more capacitors, inductors, resistors, or transmission lines in series or parallel to form individual components, and/or the electrically conductive pattern 128 may include various circuits such as filters, splitters, attenuators, diplexers, etc.

Turning now to FIG. 6, in some embodiments, the component assembly 100 may be mounted on a mounting surface 20 of a device 10. The device 10 may be a printed circuit board (PCB) or the like. For instance, the second electrically conductive layer 114 of the heat sink component 102 may contact the mounting surface 20 of the device 10. More particularly, in some embodiments, the second electrically conductive layer 114 may contact an electrically and/or thermally conductive terminal or the like defined in or on the mounting surface 20 of the device 10, which may direct heat and/or electrical current from the component assembly 100 into the device 10.

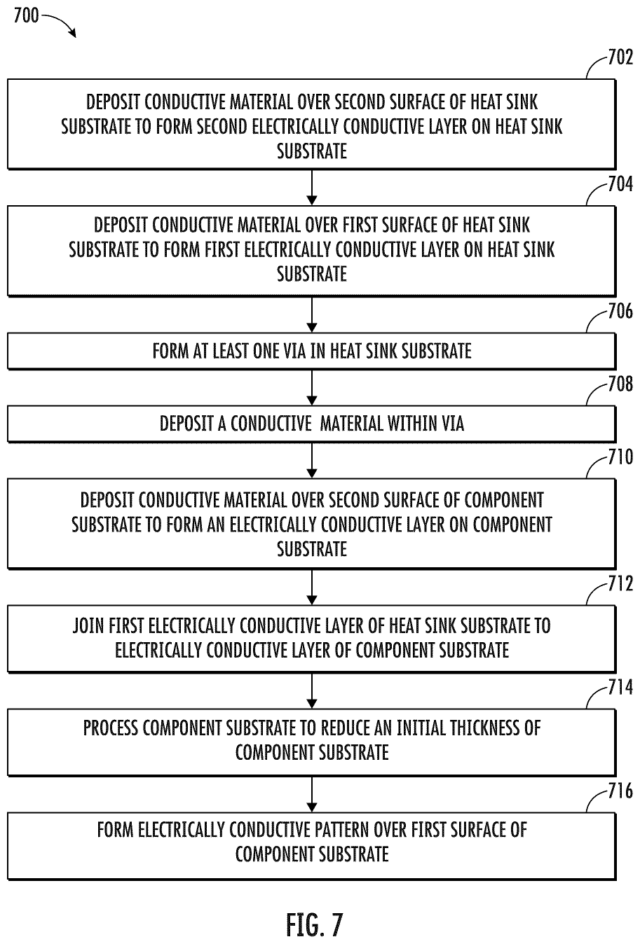

The present disclosure also includes methods of forming component assemblies, such as the component assembly 100. Referring to FIG. 7, an exemplary method 700 of forming a component assembly 100 includes (702) depositing a conductive material over a second surface 110 of a heat sink substrate 106 of a heat sink component 102 to form a second electrically conductive layer 114 on the heat sink substrate 106. As described herein, the heat sink substrate 106 includes a thermally conductive material that is electrically non-conductive, and the second surface 110 of the heat sink substrate 106 is opposite a first surface 108 of the heat sink substrate 106. In some embodiments, the method 700 also includes (704) depositing a conductive material over the first surface 108 of the heat sink substrate 106 to form a first electrically conductive layer 112 on the heat sink substrate 106.

Keeping with FIG. 7, the method 700 can also include (706) forming at least one via 118 in the heat sink substrate 106. The via(s) 118 can extend from the first surface 108 of the heat sink substrate 106 to the second surface 110 of the heat sink substrate 106. For example, in embodiments including both layers 112, 114, the via(s) 118 can extend between the first electrically conductive layer 112 on the first surface 108 of the heat sink substrate 106 and the second electrically conductive layer 114 on the second surface 110 of the heat sink substrate 106. In such embodiments, the method 700 can include (708) depositing a conductive material within the at least one via 118 to electrically connect the first electrically conductive layer 112 and the second electrically conductive layer 114. The conductive material may be the same material that forms the first electrically conductive layer 112 and/or the second electrically conductive layer 114. The one or more vias 118 may be formed by drilling or otherwise defining the via(s) 118 in the heat sink substrate 106.

Further, the method can also include (710) depositing a conductive material over a second surface 124 of a component substrate 120 of an electrical component 104 to form an electrically conductive layer 126 on the component substrate 120. In the depicted embodiment, the method 700 further includes (712) joining the first electrically conductive layer 112 of the heat sink substrate 106 to the electrically conductive layer 126 of the component substrate 120. The component substrate 120 can be disposed on the heat sink substrate 106 such that the second surface 124 of the component substrate 120 is adjacent the first surface 108 of the heat sink substrate 106.

As one example, joining the first electrically conductive layer 112 of the heat sink substrate 106 to the electrically conductive layer 126 of the component substrate 120 may include bonding the first electrically conductive layer 112 to the electrically conductive layer 126 of the component substrate 120 with an adhesive. As described in greater detail elsewhere herein, (704) depositing the conductive material over the first surface 108 of the heat sink substrate 106 to form the first electrically conductive layer 112 and/or (710) depositing the conductive material over the second surface 124 of the component substrate 120 to form the electrically conductive layer 126 may include defining a gap 116 in the conductive material for receipt of the adhesive. Of course, the heat sink component 102 and the electrical component 104 may be joined together in other ways, such as described herein.

As shown in FIG. 7, the method 700 can include (714) processing the component substrate 120 to reduce an initial thickness t_{csub_i} of the component substrate 120 such that the component substrate 120 has a processed thickness t_{csub} less than about 600 μm. Processing the component substrate 120 may include grinding an original first surface 122 of the component substrate 120, thereby defining a new first surface 122′ of the component substrate 120, which is separated from the second surface 124 by the component substrate thickness t_{csub}. Further, as described elsewhere herein, the component substrate 120 can be joined to the heat sink substrate 106 prior to processing the component substrate 120 to reduce its thickness; for example, the heat sink substrate 106 can provide additional stability to the component substrate 120 to facilitate a relatively substantial reduction in thickness such that the resulting component thickness t_{csub} is relatively thin. For instance, the heat sink component 102 can reinforce the electrical component 104 such that the component substrate 120 may be processed or thinned to a relatively extreme level, e.g., without warping or cracking. In some embodiments, the component substrate 120 may be processed to about one half (about 50%) or less of its initial thickness t_{csub_i}, such as to about one third (about 33%), to about one fourth (about 25%), about one fifth (about 20%), to about one sixth (about 17%), to about one eighth (about 12.5%) or less of the initial thickness t_{csub_i} of the component substrate 120.

After processing the component substrate 120 to reduce its thickness t_{csub}, the method 700 can include (716) forming an electrically conductive pattern 128 over the first surface 122′ of the component substrate 120 of the electrical component 104. As described herein, the electrically conductive pattern 128 may include one or more thin film components, one or more conductive lines or traces, or any other suitable conductive element. For example, forming the electrically conductive pattern 128 may include depositing conductive material to form at least one of a capacitor, an inductor, a resistor, a transmission line, a filter, a splitter, an attenuator, or a diplexer. As shown in FIGS. 1 and 6, the electrically conductive pattern 128 in the depicted embodiment of the component assembly 100 includes a resistive element 134 connected between a first terminal 130 and a second terminal 132, such that (716) forming the electrically conductive pattern 128 includes forming the first terminal 130, the second terminal 132, and the resistive element 134 over the first surface 122′ of the component substrate 120, e.g., by depositing conductive material over the first surface 122′ to define the first terminal 130, the second terminal 132, and the resistive element 134. However, the electrically conductive pattern 128 may have any desired configuration.

The conductive material may be deposited on the first surface 108 and/or the second surface 110 of the heat sink substrate 106 and the second surface 124 of the component substrate 120 using any suitable method or technique. For example, a subtractive, semi-additive, or fully additive process may be employed with panel or pattern electroplating of the electrically conductive material followed by print and etch steps to define patterned conductive layers. Photolithography, plating (e.g., electrolytic), sputtering, vacuum deposition, printing, or other techniques may be used to form the electrically conductive layers. For example, a thin layer (e.g., a foil) of an electrically conductive material may be adhered (e.g., laminated) to a surface of a substrate, which may be a dielectric material. The thin layer of electrically conductive material may be selectively etched using a mask and photolithography to produce a desired pattern of the electrically conductive material on the surface of the substrate.

These and other modifications and variations of the present invention may be practiced by those of ordinary skill in the art, without departing from the scope of the present invention. In addition, it should be understood that aspects of the various embodiments may be interchanged both in whole or in part. Further, those of ordinary skill in the art will appreciate that the foregoing description is by way of example only and is not intended to limit the invention so further described in such appended claims.

1. A component assembly, comprising:
a heat sink component including:
a heat sink substrate comprising a thermally conductive material that is electrically non-conductive, the heat sink substrate having a first surface and a second surface opposite the first surface, and
a second electrically conductive layer formed over the second surface of the heat sink substrate; and
an electrical component including:
a component substrate having a first surface and a second surface opposite the first surface, and
an electrically conductive pattern formed over the first surface of the component substrate,
wherein the electrical component is disposed on the heat sink component such that the second surface of the component substrate is adjacent the first surface of the heat sink substrate.

2. The component assembly of claim 1, wherein the heat sink component further comprises a first electrically conductive layer formed over the first surface of the heat sink substrate.

3. The component assembly of claim 2, wherein the electrical component further comprises an electrically conductive layer formed over the second surface of the component substrate.

4. The component assembly of claim 3, wherein the first electrically conductive layer of the heat sink component is joined to the electrically conductive layer of the electrical component.

5. The component assembly of claim 4, wherein the first electrically conductive layer is joined to the electrically conductive layer of the electrical component with an epoxy.

6. The component assembly of claim 4, wherein the first electrically conductive layer is a first metal layer and the electrically conductive layer of the electrical component is a component metal layer, and wherein the first metal layer is joined to the component metal layer through a metalized connection.

7. The component assembly of claim 4, wherein the first electrically conductive layer extends over the entirety of the first surface of the heat sink substrate and the electrically conductive layer of the electrical component extends over the entirety of the second surface of the component substrate.

8. The component assembly of claim 4, wherein a gap is formed in at least one of the first electrically conductive layer or the electrically conductive layer of the electrical component for receipt of an adhesive.

9. The component assembly of claim 2, wherein the first electrically conductive layer extends over the entirety of the first surface of the heat sink substrate.

10. The component assembly of claim 2, wherein the first electrically conductive layer is a first metal layer and the second electrically conductive layer is a second metal layer.

11. The component assembly of claim 2, wherein at least one via extends through the heat sink substrate from the first electrically conductive layer to the second electrically conductive layer.

12. The component assembly of claim 11, wherein the at least one via includes a conductive material to electrically connect the first electrically conductive layer and the second electrically conductive layer.

13. The component assembly of claim 1, wherein the electrical component further comprises an electrically conductive layer formed over the second surface of the component substrate.

14. The component assembly of claim 13, wherein the electrically conductive layer of the electrical component extends over the entirety of the second surface of the component substrate.

15. The component assembly of claim 1, wherein the electrical component is joined to the heat sink component with an adhesive.

16. The component assembly of claim 1, wherein the component substrate has a thickness less than about 600 μm.

17. The component assembly of claim 1, wherein a ratio of a thickness of the heat sink substrate to a thickness of the component substrate is at least about 0.2.

18. The component assembly of claim 1, wherein a ratio of an overall thickness of the component assembly to a thickness of the component substrate is at least about 2.

19. The component assembly of claim 1, wherein the electrically conductive pattern includes at least one of a capacitor, an inductor, a resistor, a transmission line, a filter, a splitter, an attenuator, or a diplexer.

20. A method of forming a component assembly, the method comprising:
depositing a conductive material over a second surface of a heat sink substrate to form a second electrically conductive layer on the heat sink substrate, the heat sink substrate comprising a thermally conductive material that is electrically non-conductive, the second surface of the heat sink substrate opposite a first surface of the heat sink substrate; and
forming an electrically conductive pattern over a first surface of a component substrate of an electrical component, the component substrate having a second surface opposite the first surface,
wherein the component substrate is disposed on the heat sink substrate such that the second surface of the component substrate is adjacent the first surface of the heat sink substrate.
